(19) United States
(12) Patent Application Publication
(10) Pub. No.: US 2025/0343518 A1
(43) Pub. Date: Nov. 6, 2025

(54) HIGH EFFICIENCY POWER AMPLIFIER WITH DIRECT BATTERY SUPPLY CONNECTION, RADIO FREQUENCY MODULE, AND MOBILE DEVICE INCLUDING THE SAME

(71) Applicant: SKYWORKS SOLUTIONS, INC., Irvine, CA (US)

(72) Inventor: David Richard Pehlke, Westlake Village, CA (US)

(21) Appl. No.: 19/192,540

(22) Filed: Apr. 29, 2025

Related U.S. Application Data
(60) Provisional application No. 63/641,013, filed on May 1, 2024.

(51) Int. Cl. H03F 3/21; H03F 3/213

(52) U.S. Cl. CPC H03F 3/211; H03F 3/213; H03F 2200/24; H03F 2200/451

(57) ABSTRACT

A radio frequency module that includes a power amplifier and a load modulator. The power amplifier is configured to directly receive a battery voltage and to receive a radio frequency input signal. The power amplifier is further configured to amplify the radio frequency input signal using the battery voltage to generate a radio frequency output signal. The load modulator is configured to load-modulate the power amplifier. The radio frequency module may be included in a front end module, which may itself be included in a mobile device.

### CROSS-REFERENCE TO RELATED APPLICATIONS

This application claims priority under 35 U.S.C. § 119(e) to U.S. Provisional Patent Application 63/641,013 titled HIGH EFFICIENCY POWER AMPLIFIER WITH DIRECT BATTERY SUPPLY CONNECTION, RADIO FREQUENCY MODULE, AND MOBILE DEVICE INCLUDING THE SAME, filed on May 1, 2024, and hereby incorporated by reference in its entirety for all purposes.

### BACKGROUND

### Field

Embodiments of the present disclosure relate to electronic systems, and in particular, to radio frequency front end (RFFE) modules used in wireless communication equipment.

### Description of the Related Technology

Radio frequency (RF) is a common term for a range of frequency of electromagnetic radiation typically used to produce and detect radio waves. Such a range can be from about 30 kHz to 300 GHz. Wireless communication devices often include front-end circuitry for processing or conditioning RF signals at an incoming or outgoing frequency or signal port. RF front-end modules may be components of receiver, transmitter, or transceiver systems associated with a wireless device.

RF front-end design may include a number of considerations, including complexity, substrate compatibility, performance, and integration. It can be desirable for wireless devices to save components and parts in design.

### SUMMARY

In accordance with an aspect of the present disclosure, a radio frequency module is provided. The radio frequency module comprises a power amplifier and a load modulator. The power amplifier is configured to directly receive a battery voltage and to receive a radio frequency input signal. The power amplifier is further configured to amplify the radio frequency input signal using the battery voltage to generate a radio frequency output signal. The load modulator is configured to load-modulate the power amplifier. The radio frequency module may be included in a front end module, which may itself be included in a mobile device.

In one example, the load modulation is performed in fixed steps.

In other examples, the load modulator is configured to adjust a load line of the power amplifier.

In some examples, the load line is adjusted incrementally.

In one example, the radio frequency module further comprises control circuitry configured to control operation of the power amplifier. In some examples the control circuitry is configured to adjust input bias of the power amplifier. In some examples, the input bias is adjusted incrementally. In a further example, the control circuitry is configured to receive a detection of the battery voltage and to adjust input bias based on the detected battery voltage. In another example the control circuitry is configured to receive feedback from an output side of the power amplifier and to adjust the input bias based on the received feedback. In accordance with this example, the feedback indicates at least one of a target gain, an output power, and an input bias of the power amplifier.

In accordance with another aspect of the present disclosure, a wireless device is provided. The wireless device comprises an antenna configured to transmit and receive radio frequency signals, and a front end system coupled to the antenna. The front end system includes a power amplifier configured to directly receive a battery voltage and to receive a radio frequency input signal, the power amplifier being further configured to amplify the radio frequency input signal using the battery voltage to generate a radio frequency output signal, and a load modulator configured to load-modulate the power amplifier.

### BRIEF DESCRIPTION OF THE DRAWINGS

FIG. 1 illustrates a schematic block diagram of an exemplary wireless device.

FIG. 2 illustrates a schematic block or circuit diagram of a conventional concept of a radio frequency module.

FIG. 3 illustrates a schematic block or circuit diagram of a radio frequency module according to an aspect of the present disclosure.

FIG. 4 illustrates a schematic block or circuit diagram of a radio frequency module according to an aspect of the present disclosure.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

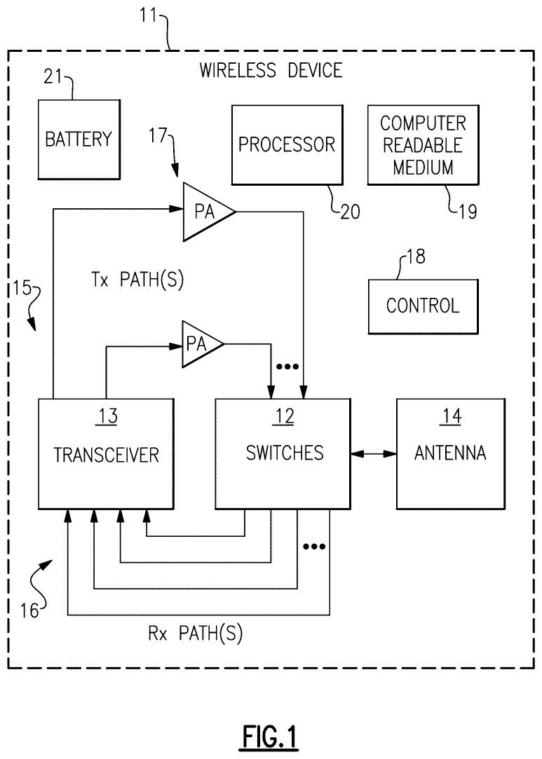

FIG. 1 is a schematic block diagram of an example of a wireless device 11. The wireless device 11 can include a power amplifier bias circuit implementing one or more features of the present disclosure in a control component 18. The power amplifier bias circuit can include a control circuit and a primary biasing circuit.

The example wireless device 11 depicted in FIG. 1 can represent a multi-band and/or multi-mode device such as a multi-band/multi-mode mobile phone. In certain embodiments, the wireless device 11 can include a switch module 12, a transceiver 13, an antenna 14, power amplifiers 17, a control component 18, a computer readable medium 19, a processor 20, and a battery 21.

The transceiver 13 can generate RF signals for transmission via the antenna 14. Furthermore, the transceiver 13 can receive incoming RF signals from the antenna 14.

It will be understood that various functionalities associated with the transmission and receiving of RF signals may be achieved by one or more components that are collectively represented in FIG. 1 as the transceiver 13. For example, a single component may be configured to provide both transmitting and receiving functionalities. In another example, transmitting and receiving functionalities may be provided by separate components.

Similarly, it will be understood that various antenna functionalities associated with the transmission and receiving of RF signals may be achieved by one or more components that are collectively represented in FIG. 1 as the antenna 14. For example, a single antenna may be configured to provide both transmitting and receiving functionalities. In another example, transmitting and receiving functionalities may be provided by separate antennas. In yet another example, different bands associated with the wireless device 11 may be provided with different antennas.

In FIG. 1, one or more output signals from the transceiver 13 are depicted as being provided to the antenna 14 via one or more transmission paths 15. In the example shown, different transmission paths 15 can represent output paths associated with different bands and/or different power outputs. For instance, the two example power amplifiers 17 shown can represent amplifications associated with different power output configurations (e.g., low power output and high power output), and/or amplifications associated with different bands. Although FIG. 1 illustrates a configuration using two transmission paths 15, the wireless device 11 can include more or fewer transmission paths 15.

The power amplifiers 17 may be used to amplify a wide variety of RF signals. For example, one or more of the power amplifiers 17 can receive an enable signal that may be used to pulse the output of the power amplifier to aid in transmitting a wireless local area network (WLAN) signal, such as a WLAN 802.11be signal, or any other suitable pulsed signal. In certain embodiments, one or more of the power amplifiers 17 are configured to amplify a Wi-Fi signal. Each of the power amplifiers 17 need not amplify the same type of signal. For example, one power amplifier can amplify a WLAN signal, while another power amplifier can amplify, for example, another WLAN signal, a Global System for Mobile (GSM) signal, a code division multiple access (CDMA) signal, a W-CDMA signal, a Long Term Evolution (LTE) signal, or a 5G signal.

One or more features of the present disclosure may be implemented in the foregoing example communication standards, modes and/or bands, and in other communication standards.

In FIG. 1, one or more detected signals from the antenna 14 are depicted as being provided to the transceiver 13 via one or more receiving paths 16. In the example shown, different receiving paths 16 can represent paths associated with different bands. Although FIG. 1 illustrates a configuration using four receiving paths 16, the wireless device 11 may be adapted to include more or fewer receiving paths 16.

To facilitate switching between receive and transmit paths, the switch module 12 may be configured to electrically connect the antenna 14 to a selected transmit or receive path. Thus, the switch module 12 can provide a number of switching functionalities associated with an operation of the wireless device 11. In certain embodiments, the switch module 12 can include a number of switches configured to provide functionalities associated with, for example, switching between different bands, switching between different power modes, switching between transmission and receiving modes, or some combination thereof. The switch module 12 can also be configured to provide additional functionality, including filtering and/or duplexing of signals.

FIG. 1 shows that in certain embodiments, a control component 18 may be provided for controlling various control functionalities associated with operations of the switch module 12, the power amplifiers 17, and/or other operating component(s). The control component 18 may be implemented on the same die as the power amplifier 17 in certain implementations. The control component 18 may be implemented on a different die than the power amplifier 17 in some implementations. Non-limiting examples of the control component 18 that include a control circuit and a bias circuit to achieve a desired balance of EVM reduction and OOB emissions are described herein in greater detail.

In certain embodiments, a processor 20 may be configured to facilitate implementation of various processes described herein. For the purpose of description, embodiments of the present disclosure may also be described with reference to flowchart illustrations and/or block diagrams of methods, apparatus (systems) and computer program products. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the acts specified in the flowchart and/or block diagram block or blocks.

In certain embodiments, these computer program instructions may also be stored in a computer-readable medium or memory 19 that can direct a computer or other programmable data processing apparatus to operate in a particular manner, such that the instructions stored in the computer-readable memory produce an article of manufacture including instructions which implement the acts specified in the flowchart and/or block diagram block or blocks. The computer program instructions may also be loaded onto a computer or other programmable data processing apparatus to cause a series of operations to be performed on the computer or other programmable apparatus to produce a computer implemented process such that the instructions that execute on the computer or other programmable apparatus provide instructions for implementing the acts specified in the flowchart and/or block diagram block or blocks.

The battery 21 may be any suitable battery for use in the wireless device 11, including, for example, a lithium-ion battery.

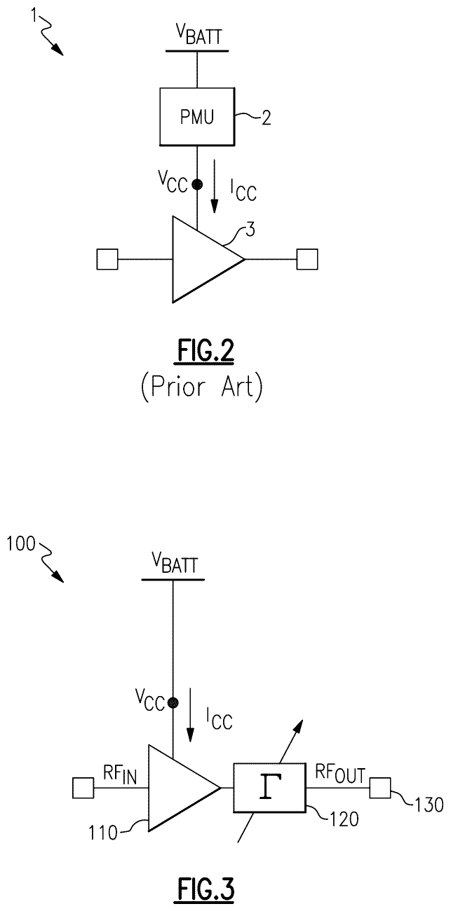

FIG. 2 illustrates a concept of a conventional radio frequency module 1 used in e.g., transmitter technologies. The conventional radio frequency module 1 comprises a power management unit (PMU) 2, which may be replaced by a power management integrated circuit (PMIC), and a power amplifier 3. The PMU 2 is configured to receive a battery voltage, denoted in FIG. 2 as V_{BATT} and to generate, based on the battery voltage V_{BATT}, a supply voltage V_{CC} for the power amplifier 3. In many transmitter technologies, the supply voltage and current provided by the PMU 2 to the power amplifier may allow the power amplifier 3 to be operated in an Envelope Tracking (ET) mode, or an Average Power Tracking (APT) mode. In some applications, the PMU 2 may include a Buck power supply, a Boost power supply, or a Buck-Boost power supply to provide a steady supply voltage to the power amplifier 3, despite a battery voltage that may vary over time and use.

In this disclosure, it is proposed to efficiently simplify design of a radio frequency module so as to save space occupied by components and/or to save costs caused by components, such as a power management unit (PMU) or a power management integrated circuit (PMIC). In other words, it is proposed to eliminate the PMU or PMIC so as to help reduce system parts count, size, and cost of a radio frequency module and/or a wireless device comprising such a radio frequency module. It is noted that besides the PMU or PMIC, an envelope tracking (ET) modulator may be eliminated so as to help reduce system parts count, size, and cost of a radio frequency module and/or a wireless device comprising such a radio frequency module.

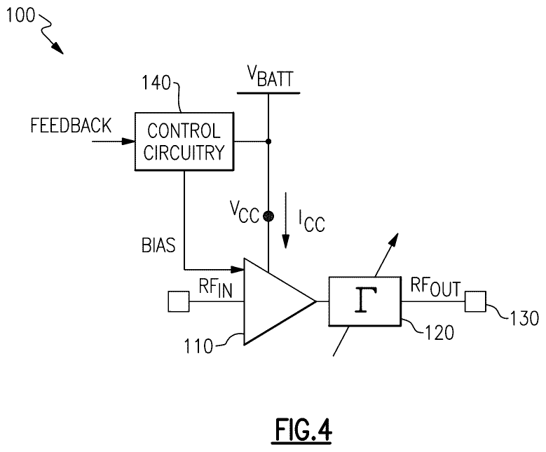

FIG. 3 illustrates in a block diagram an exemplary radio frequency module 100. For example, it may be implemented in the wireless device 11, wherein this is not limited herein.

The radio frequency module 100 comprises a power amplifier 110 and a load modulator 120. In other words, the power amplifier 110 is a load-modulated amplifier.

The power amplifier 110 is configured to directly receive a battery voltage, denoted in FIG. 3 as V_{BATT}. For example, the battery voltage V_{BATT} may be provided by the battery 21.

Further, the power amplifier 110 is configured to receive a radio frequency input signal RF_{IN}. In addition, the power amplifier 110 is configured to amplify the radio frequency input signal RF_{IN} using the battery voltage V_{BATT} to generate a radio frequency output signal RF_{OUT}.

For example, the output signal RF_{OUT} may be provided to a load 130. By way of example, the load 130 may be the antenna 14 or the like.

According to the embodiment of the present disclosure illustrated in FIG. 3, in contrast to the conventional concept illustrated in FIG. 2, the PMU 2 is eliminated by enabling load modulation directly from the battery voltage V_{BATT}. In other words, the load-modulated power amplifier 110 is enabled to directly receive the battery voltage V_{BATT}. This may help to reduce the parts count, size, and/or cost of the radio frequency module 100.

In at least some embodiments, the load modulation may be performed incrementally, e.g., in fixed steps. This may help to enable high efficiency at backed-off power levels.

Further, in at least some embodiments, the load modulator may be configured to adjust a load line of the power amplifier. For example, the load line may be adjusted incrementally.

This may help to enable re-sizing the power amplifier 110 for close-to-maximum power efficiency across power for an upper portion of its dynamic range.

For example, the power amplifier 110 may comprise a bipolar transistor having an emitter, a base, and a collector. The emitter of the bipolar transistor may be electrically connected to a power low supply voltage, which can be, for example, a ground supply. Additionally, the radio frequency input signal RF_{IN} may be provided to the base of the bipolar transistor, and the bipolar transistor amplifies the RF signal to generate an amplified RF signal at the collector. The bipolar transistor may be any suitable device. In one implementation, the bipolar transistor may be a heterojunction bipolar transistor (HBT).

FIG. 4 illustrates in a block diagram another example of the radio frequency module 100.

According to FIG. 4, the radio frequency module 100 may further comprise control circuitry 140 configured to control operation of the power amplifier 110. The control circuitry 140 is coupled to the power amplifier 110. For example, the control circuitry 140 may be configured to adjust input bias of the power amplifier. In at least some embodiments, the input bias may be adjusted incrementally.

In at least some embodiments, the control circuitry 140 may be configured to detect the battery voltage V_{BATT}. For example, the control circuitry 140 may comprise or may be coupled to a voltage detector. In at least some embodiments, the control circuitry 140 is configured to receive a detection, e.g., a detection signal, of the battery voltage V_{BATT}. Further, in at least some embodiments, the control circuitry 140 may be configured to adjust the input bias provided to the power amplifier 110 based on the detected battery voltage V_{BATT}.

Further, in at least some embodiments, the control circuitry 140 may be configured to receive feedback from an output side of the power amplifier 110. The control circuitry 140 may be configured to adjust the input bias based on the received feedback.

For example, the feedback may indicate at least one of a target gain, an output power, and an input bias of the power amplifier. In at least some embodiments, the control circuitry 140 may be configured to adjust at least one of the target gain, an output power, and an input bias based on the feedback. It is noted that these may be adjusted across a changing battery voltage V_{BATT} curve, thereby helping to smooth the performance of the power amplifier 110.

According to an aspect of the present disclosure, adding the at least one of the detection of the battery voltage V_{BATT}, the control of bias, and the load line adjustment, operation may be improved in terms of optimizing across uncertain discharge, temperature, VSWR, and other general conditions for high performance and significant cost advantage.

According to the present disclosure, it is not necessary to provide a PMU, a PMIC or an ET modulator since load modulation directly from the battery voltage V_{BATT} is enabled, and therefore part counts, size and cost may be reduced.

Some of the embodiments described above have provided examples in connection with wireless devices or mobile phones. However, the principles and advantages of the embodiments can be used for any other systems or apparatus that have needs for power amplifiers.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of aspects and embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of aspects and embodiments of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A radio frequency module comprising:
a power amplifier configured to directly receive a battery voltage and to receive a radio frequency input signal, the power amplifier being further configured to amplify the radio frequency input signal using the battery voltage to generate a radio frequency output signal; and
a load modulator configured to load-modulate the power amplifier.

2. The radio frequency module of claim 1 wherein the load modulation is performed in fixed steps.

3. The radio frequency module of claim 1 wherein the load modulator is configured to adjust a load line of the power amplifier.

4. The radio frequency module of claim 1 wherein the load line is adjusted incrementally.

5. The radio frequency module of claim 1 further comprising control circuitry configured to control operation of the power amplifier.

6. The radio frequency module of claim 5 wherein the control circuitry is configured to adjust input bias of the power amplifier.

7. The radio frequency module of claim 6 wherein the input bias is adjusted incrementally.

8. The radio frequency module of claim 5 wherein the control circuitry is configured to receive a detection of the battery voltage and to adjust input bias based on the detected battery voltage.

9. The radio frequency module of claim 5 wherein the control circuitry is configured to receive feedback from an output side of the power amplifier and to adjust the input bias based on the received feedback.

10. The radio frequency module of claim 9 wherein the feedback indicates at least one of a target gain, an output power, and an input bias of the power amplifier.

11. A wireless device comprising:
an antenna configured to transmit and receive radio frequency signals; and
a front end system coupled to the antenna and including a power amplifier configured to directly receive a battery voltage and to receive a radio frequency input signal, the power amplifier being further configured to amplify the radio frequency input signal using the battery voltage to generate a radio frequency output signal, and a load modulator configured to load-modulate the power amplifier.

12. The wireless device of claim 11 wherein the load modulation is performed in fixed steps.

13. The wireless device of claim 11 wherein the load modulator is configured to adjust a load line of the power amplifier.

14. The wireless device of claim 11 wherein the load line is adjusted incrementally.

15. The wireless device of claim 11 further comprising control circuitry configured to control operation of the power amplifier.

16. The wireless device of claim 15 wherein the control circuitry is configured to adjust input bias of the power amplifier.

17. The wireless device of claim 16 wherein the input bias is adjusted incrementally.

18. The wireless device of claim 15 wherein the control circuitry is configured to receive a detection of the battery voltage and to adjust input bias based on the detected battery voltage.

19. The wireless device of claim 15 wherein the control circuitry is configured to receive feedback from an output side of the power amplifier and to adjust the input bias based on the received feedback.

20. The wireless device of claim 19 wherein the feedback indicates at least one of a target gain, an output power, and an input bias of the power amplifier.
